(19) United States
(12) Patent Application Publication
(10) Pub. No.: US 2026/0050035 A1
(43) Pub. Date: Feb. 19, 2026

(54) TEST CIRCUIT FOR RELIABILITY TEST OF DEVICE UNDER TEST AND METHOD FOR OPERATING THE SAME

(71) Applicant: TAIWAN SEMICONDUCTOR MANUFACTURING COMPANY LTD., HSINCHU (TW)

(72) Inventor: SZU-CHUN TSAO, HSINCHU CITY (TW)

(21) Appl. No.: 18/801,872

(22) Filed: Aug. 13, 2024

(51) Int. Cl. G01R 31/319

(52) U.S. Cl. CPC G01R 31/31922; G01R 31/31924

(57) ABSTRACT

The present disclosure provides an integrated circuit, which includes a device under test (DUT) and a test circuit. The test circuit includes a clock generator, a gate control circuit, and a gate isolation circuit. The clock generator is configured to generate a clock signal. The gate control circuit is configured to convert, in response to a test enable signal being deasserted, the clock signal within a first voltage domain to generate a gate clock signal within a second voltage domain at an output terminal of the gate control circuit which is connected to a gate terminal of the DUT. The gate isolation circuit is coupled between the gate terminal of the DUT and a first input/output (I/O) pad of the integrated circuit.

### BACKGROUND

The semiconductor integrated circuit (IC) industry has grown rapidly due to advancements in IC materials and design. Each new generation of ICs features smaller and more complex circuits than the previous one. During the fabrication of semiconductor devices, one or more testing processes are typically involved, often utilizing on-chip structures for testing purposes. The existing reliability test conducted on a device under test (DUT) within an integrated circuit is limited to clock signals in the MHz range due to significant parasitic capacitance. This limitation presents challenges when attempting to perform reliability tests on the DUT with clock signals operating in the GHz range.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of an integrated circuit in accordance with some embodiments of the present disclosure.

FIG. 2 is a schematic diagram of a gate control circuit in accordance with some embodiments of the present disclosure.

FIG. 3 is a schematic diagram of a level shifter in accordance with some embodiments of the present disclosure.

FIG. 4A is a schematic diagram of a switch circuit in accordance with some embodiments of the present disclosure.

FIG. 4B is a layout diagram of the switch circuit in FIG. 4A.

FIG. 5 is a schematic diagram of a gate control circuit in accordance with some embodiments of the present disclosure.

FIG. 6A is a diagram illustrating equivalent resistance and capacitance from the I/O pad to the gate terminal of the DUT in accordance with some embodiments of the present disclosure.

FIG. 6B is a diagram illustrating equivalent resistance and capacitance from the I/O pad to the gate terminal of one of the DUTs in accordance with some embodiments of the present disclosure.

FIG. 7 is a schematic diagram of a gate control circuit in accordance with some embodiments of the present disclosure.

FIG. 8A is a diagram illustrating the components of a gate leakage current measured from the I/O pad in accordance with some embodiments of the present disclosure.

FIGS. 8B-8C are diagrams illustrating the procedure for calibrating a gate leakage current of the DUT in accordance with some embodiments of the present disclosure.

FIG. 9 is a flowchart of a method for calibrating a gate leakage current of the DUT in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

In some embodiments, a test circuit for reliability test of a device under test (DUT) is provided. The test circuit is employed in an integrated circuit. The test circuit includes a clock generator, a gate control circuit, and a gate isolation circuit. The clock generator is capable of generating a clock signal within a first voltage domain, and the gate control circuit is capable of converting the clock signal within the first voltage domain to generate a gate clock signal within a second voltage domain which is higher than the first voltage domain. The gate clock signal is provided to a gate terminal of the DUT for reliability test or stress test. The clock signal and gate clock signal can have an operating frequency within a GHz range. The gate isolation circuit is coupled between an I/O pad and the gate terminal of the DUT to prevent the gate clock signal from being affected by the parasitic capacitance of the I/O pad.

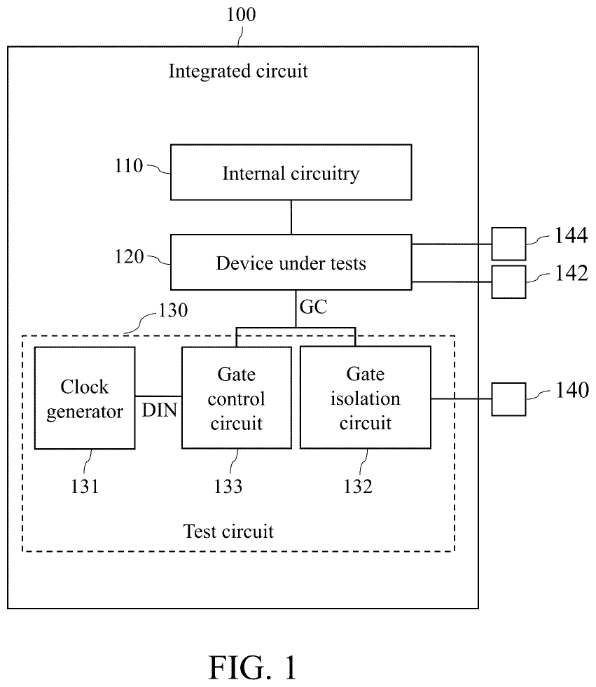

FIG. 1 is a block diagram of an integrated circuit in accordance with some embodiments of the present disclosure.

In some embodiments, the integrated circuit 100 may include internal circuitry 110, one or more devices under test (DUTs) 120, and a test circuit 130. The internal circuitry 110 may include functional digital or analog circuitry that implements functions of the integrated circuit 100. Each of the DUTs 120 may be coupled to a respective input/output (I/O) pad of the integrated circuit 100. In some embodiments, the test circuit 130 may be configured to perform one or more tests on the DUTs 120 to test its reliability. For example, the test circuit 130 may perform a GHz stress test on a designated DUT 120 to test its reliabilities for hot carrier injection (HCI), bias temperature instability (BTI), time-dependent dielectric breakdown (TDDB), etc. In some embodiments, each of the DUTs 120 may be a field-effect transistor connected between the internal circuitry 110 and a respective I/O pad.

In some embodiments, the test circuit 130 includes a clock generator 131, a gate isolation circuit 132, and a gate control circuit 133. The clock generator 131 may be a clock generator capable of generating a clock signal DIN having a frequency from a MHz range to a GHz range. For example, when a stress test within the MHz range is performed, the clock generator 131 can be set to generate a clock signal DIN within the MHz range. When a stress test within the GHz range is performed, the clock generator 131 can be set to generate a clock signal DIN within the GHz range (e.g., higher than 1 GHz). The gate isolation circuit 132 is configured to prevent from significantly decrease in signal bandwidth of the gate clock signal GC of the DUT 120. Additionally, the gate clock signal GC is not affected by the interference caused by off-chip (e.g., I/O pads 140, 142, and 144) resistances and capacitances using the gate isolation circuit 132.

In some embodiments, the clock generator 131 is implemented using core devices, and the clock signal DIN generated by the clock generator 131 may have an amplitude of approximately 0.75V. The gate control circuit 133 may be configured to convert the voltage level of the clock signal DIN generated by the clock generator 131 to a higher voltage level for use by the DUT 120, such as converting from a core-device voltage level (e.g., approximately 0.75V) to a high voltage level of approximately 2.1V. Specifically, the stress test within the MHz or GHz range performed on the DUT 120 is an on-chip test (i.e., performed within the integrated circuit 100), which is free from interference of off-chip resistances and capacitances.

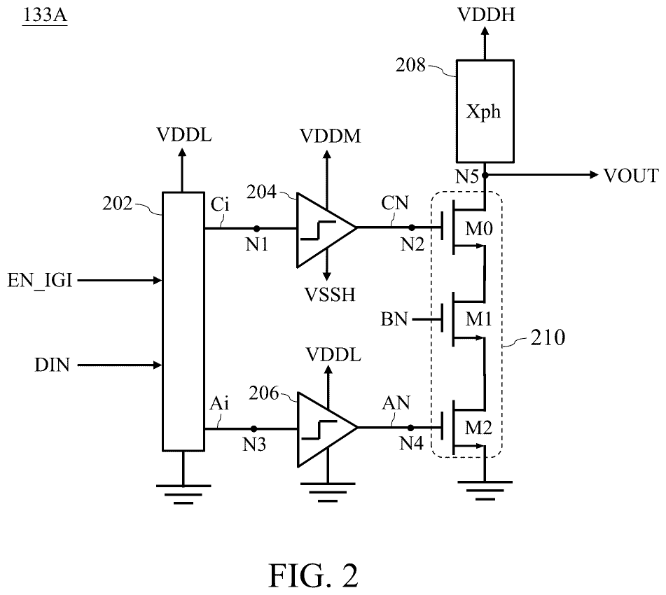

FIG. 2 is a schematic diagram of a gate control circuit in accordance with some embodiments of the present disclosure.

In some embodiments, the gate control circuit 133 shown in FIG. 1 may be implemented using the gate control circuit 133A shown in FIG. 2. The gate control circuit 133A may be supplied with various voltages, such as VDDL, VDDM, VDDH, and VSSH, by a power management circuit (not shown) within the integrated circuit 100. For example, VDDL, VDDM, and VDDH may refer to low, medium, and high power supply voltages of approximately 0.75V, 1.5V, and 2.1V, respectively. VSSH refers to a high reference voltage of approximately 0.75V. In some embodiments, the high power supply voltage VDDH is adjustable based on the stress required in the stress test.

In some embodiments, the gate control circuit 133A may include a prebuffer circuit 202, level shifters 204 and 206, a load circuit 208, and a switch circuit 210, as depicted in FIG. 2. For example, the prebuffer circuit 202 may receive the clock signal DIN generated by the clock generator 131 and a test enable signal EN_IGI, and generate signals Ai, Ci, and BN based on the test enable signal EN_IGI and the clock signal DIN. In some embodiments, the level shifter 204 is supplied with voltages VDDM and VSSH, and is configured to convert its input signal Ci within a first voltage range (e.g., between VDDL and 0V) to generate a bias voltage signal CN within a second voltage range (e.g., between VDDM and VSSH). The level shifter 206 is supplied with voltages VDDL and VSSH, and is configured to convert its input signal Ai within the first voltage range (e.g., between VDDL and 0V) to generate a bias voltage signal AN within the first voltage range.

In some embodiments, the operations of the prebuffer circuit 202 follows the control states recited in Table 1 as follows. It should be noted that the transistors M0, M1, and M2 within the switch circuit 210 are core devices which operate using a voltage of approximately 0.75V, and the voltage difference between any two terminals (e.g., VGS, VDS, and VGD) of the transistors M0, M1, and M2 is controlled to be within 0.75V for safety. Additionally, the transistors M0, M1, and M2 within the switch circuit 210 forms a 3-stack cascaded structure, and the switch circuit 210 may be regarded as a high voltage switch circuit with its output signal VOUT operating between 0 and 2.1V. The load circuit 208 may be a passive resistor or an active load circuit including a plurality of P-type transistors connected in series, each P-type transistor with a respective bias voltages.

TABLE 1

| | | (VSSH, VDDM, | | |
|---|---|---|---|---|
| EN_IGI | DIN, Ai, Ci | VDDH) | (AN, BN, CN) | VOUT |
| 0 | 0, 0, VDDL | (0.75, 1.5, 2.1) | (GND, VDDL, VDDM) | 2.1 |
| 0 | VDDL, VDDL, 0 | (0.75, 1.5, 2.1) | (VDDL, VDDL, VSSH) | ~0 |
| 1 | X | (0, 0.75, null) | (GND, GND, GND) | 0 |

In some embodiments, when the test enable signal EN_IGI is in a high-logic state (e.g., “1”), the test for measuring a gate leakage current of the DUT 120 is performed. For example, when the test enable signal EN_IGI is in the high-logic state (e.g., “1”), no matter whether the voltage level of the clock signal DIN, the power supply voltages VSSH and VDDM are 0V and 0.75V, respectively, while the power supply voltage VDDH is not supplied to its power rail (i.e., “null”). Additionally, the level shifters 204 and 206 may tie their output signals CN and AN to the ground (e.g., 0V), and the prebuffer 202 may also tie its output signal BN to the ground (e.g., 0V). It should be noted that external test equipment can measure a leakage current flowing from node N5 to the ground as a background leakage for estimating the gate leakage current of the DUT 120, and the details thereof will be described later.

In some embodiments, when the test enable signal EN_IGI is in a low logic-state (e.g., “0”), the test for measuring a gate leakage current of the DUT 120 is not performed, and the gate control circuit 133A operates in a DC (direct-current) mode. For example, when the test enable signal EN_IGI is in the low logic-state (e.g., “0”), the voltage levels of the signals Ai, BN, and Ci depend on the voltage level of the clock signal DIN. When the test enable signal EN_IGI is in the low logic state (e.g., 0V) and the voltage level of the clock signal DIN is equal to the ground voltage (e.g., 0V), the power supply voltages VSSH, VDDM, and VDDH are 0.75V, 1.5V, and 2.1V, and the signals Ai and Ci generated by the prebuffer 202 are equal to the voltages GND and VDDL, respectively. Additionally, the signals AN, BN, and CN generated by the level shifter 206, prebuffer 202, and level shifter 204 are the voltages GND, VDDL, and VDDM, respectively. When the test enable signal EN_IGI is in the low logic state (e.g., 0V) and the voltage level of the clock signal DIN is equal to the voltage VDDL (e.g., 0.75V), the power supply voltages VSSH, VDDM, and VDDH are 0.75V, 1.5V, and 2.1V, and the signals Ai and Ci generated by the prebuffer 202 are equal to the voltage VDDL and GND. Additionally the signals AN, BN, and CN generated by the level shifter 206, prebuffer 202, and level shifter 204 are the voltages VDDL, VDDL, and VSSH, respectively.

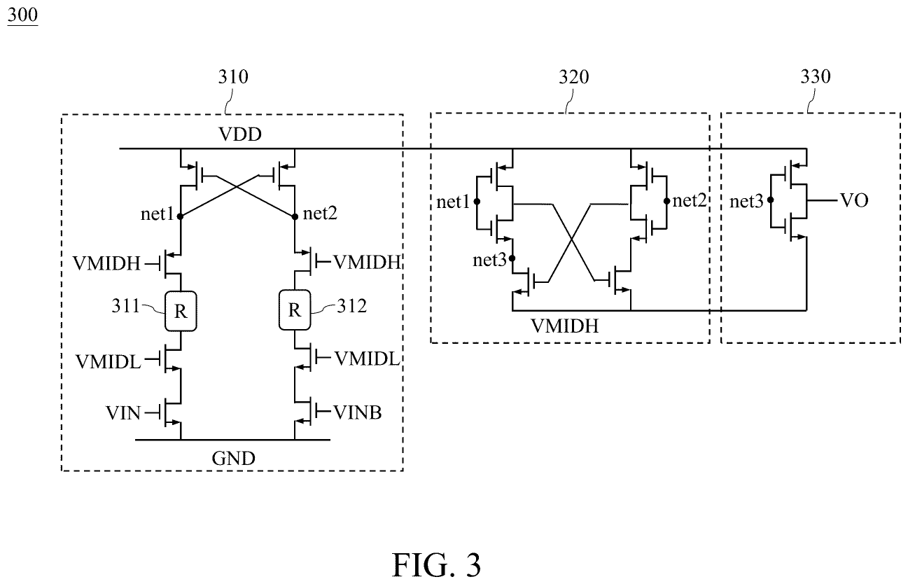

FIG. 3 is a schematic diagram of a level shifter in accordance with some embodiments of the present disclosure.

In some embodiments, the level shifters 204 and 206 may be implemented using the level shifter 300 shown in FIG. 3. For example, the level shifter 300 includes an input stage 310, a predriving stage 320, and an output stage 330. The input stage 310 may receive differential input signals VIN and VINB within the voltage range between the power supply voltage VDD and the ground, and generate a first voltage signal and a second voltage signal at node net1 and net2. It should be noted that the first voltage signal and the second voltage at node net1 and net2 are not rail-to-rail signals (i.e., swing between VDD and GND). The first voltage signal and the second voltage signal are sent to the predriving stage 320 to generate a third voltage signal at node net3 within a shifted voltage range between the power supply voltage VDD and the middle high power supply voltage VMIDH. The third voltage signal at node net3 is sent to the output stage 330 to generate an output voltage signal VO of the level shifter 300.

In some embodiments, the resistor devices 311 and 312 may be implemented using passive resistors with substantially equal resistances. In some other embodiments, the same type diode-connected transistors can be used to implement the resistor devices 311 and 312. For example, for the diode-connected configuration of an N-type transistor, the gate terminal is connected to the drain terminal of the N-type transistor to implement a resistor. Similarly, for the diode-connected configuration of a P-type transistor, the gate terminal is also connected to the drain terminal of the P-type transistor to implement a resistor.

It should be noted that the level shifters 204 and 206 shown in FIG. 2 may have circuit structures similar to the level shifter 300 shown in FIG. 3, however, in order to balance the delay of the level shifters 204 and 206, the resistances of the resistor devices 311 and 312 of the level shifter 204 could be different from those of the level shifter 206. Specifically, the level shifter 204 operates within a relatively high voltage range (e.g., between 0.75V and 1.5V), while the level shifter 206 operate within a relatively low voltage range (e.g., between 0.75V and 0V). The resistor devices 311 and 312 may be designed to have resistances close to 0 for the level shifter 206, while the resistances of the resistor devices 311 and 312 may be designed to ensure all transistors in the level shifters 204 and 206 to operate within a safe voltage range.

In some embodiments, with the configuration of power supply voltages VDDH, VDDHM, VDDL, and VSSH in the DC operation mode as described in the embodiment of FIG. 2, the power supply voltages VMIDH, VMIDL, VDD, and GND may be 0.75V, 0.75V, 1.5V, and 0V for the level shifter 204, while the power supply voltages VMIDH, VMIDL, VDD, and GND may be 0V, 0.75V, 0.75V, and 0V for the level shifter 206. Accordingly, the transistors within the level shifters 204 and 206 can operate within a safe voltage range, i.e., the voltage difference between any two terminals (e.g., VGS, VDS, and VGD) of each transistor (e.g., core devices) is within 0.75V.

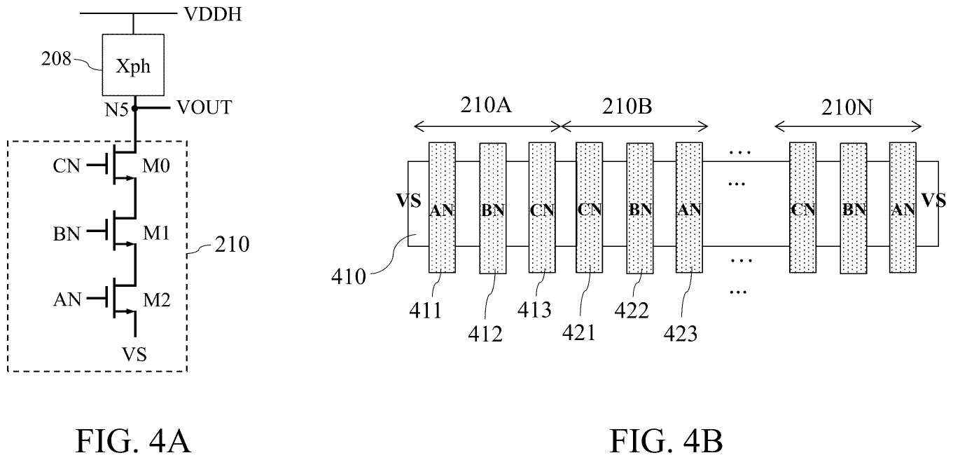

FIG. 4A is a schematic diagram of a switch circuit in accordance with some embodiments of the present disclosure. FIG. 4B is a layout diagram of the switch circuit in FIG. 4A.

In some embodiments, transistors M0 to M2 in the switch circuit 210 may be supplied with different bias voltages, such as CN, BN, and AN, respectively, as depicted in FIG. 4A. For purposes of description, the voltages VDDL, VDDH, and VS are approximately 0.75V, 2.1V, and 0V, respectively. The configurations of the voltages CN, BN, AN, and VOUT are illustrated in Table 2 as follows.

TABLE 2

| Voltage | Switch OFF | Switch ON |
|---|---|---|
| CN | VDDL + VDDL | VDDL |
| BN | VDDL | VDDL |
| AN | VS | VDDL |
| VOUT | VDDH | VS |

In some embodiments, transistors M0, M1, and M2 within the 3-stack cascaded structure of the switch circuit 210 are core devices, and the voltage difference between any two terminal (e.g., VGS, VGD, VDS) in each transistor M0 to M2 can be kept within the tolerance voltage range (e.g., equal to or lower than 0.75V) using the voltage configurations for bias voltages CN, BN, and AN in Table 2.

In some embodiments, when the gate control circuit 133A is in the DC operation mode (i.e., EN_IGI=0) and the voltage level of the clock signal DIN is equal to the ground voltage (e.g., 0V), the bias voltages CN, BN, and AN provided to the gate terminals of transistors M0, M1, and M2 are equal to the voltage VDDL (e.g., 0.75V), turning on transistors M0 to M2 within the switch circuit 210. Specifically, the gate-source voltage of transistor M2 is approximately 0.75V which is larger than the threshold voltage Vt of transistor M2, turning on transistor M2. Similarly, the voltage at the drain terminal of transistor M2, which is also the source terminal of transistor M1, is approximately equal to voltage VS (e.g., 0V). This results in the gate-source voltage of transistor M1 is approximately 0.75V, turning on transistor M1. Likewise, the voltage at the drain terminal of transistor M1, which is also the source terminal of transistor M0, may be pulled down to the voltage VS (e.g., 0V) through transistor M1 and M2. Thus, the gate-source voltage of transistor M0 is 0.75V which is larger than the threshold voltage Vt of transistor M0, turning on transistor M0. As a result, a grounding path from node N5 to the ground voltage VS is conducted through transistor M0 to M2, pulling down the voltage VOUT to the ground voltage VS.

In some embodiments, when the gate control circuit 133A is in the DC operation mode (i.e., EN_IGI=0) and the voltage level of the clock signal DIN is equal to the voltage VDDL (e.g., 0.75V), the bias voltages CN, BN, and AN provided to the gate terminals of transistors M0, M1, and M2 are VDDL+VDDL (e.g., 1.5V), VDDL (e.g., 0.75V), and VS (e.g., 0V), respectively, turning off transistors M0 to M2 within the switch circuit 210. Specifically, since transistors M0 to M2 are turned off, the output voltage VOUT is pulled up to the voltage VDDH (e.g., 2.1V) through the load circuit 208 (e.g., a passive resistor or an active load), and the gate-drain voltage of transistor M0 is within safe voltage range (e.g., less than or equal to 0.75V). Since transistor M0 is turned off, the source voltage of transistor M0 is close to its gate voltage CN (e.g., 1.5V), and the gate-drain voltage of transistor M1 is within safe voltage range. Since transistor M1 is turned off, the source voltage of transistor M1 is close to its gate voltage BN (e.g., 0.75V), and the gate-drain voltage of transistor M2 is within safe voltage range. Similarly, the gate-source voltage of transistor M2 is also within the safe voltage range.

It should be noted that the integrated circuit 100 shown in FIG. 1 includes a plurality of DUTs 120, and each DUT 120 may have a respective gate control circuit 133A, which includes one switch circuit 210. For purposes of description, the switch circuits 210A to 210N correspond to the DUTs 120, and each of the switch circuits 210A to 210N shown in FIG. 4B may have substantially identical layout as the switch circuit 210 shown in FIG. 4A.

In some embodiments, the layout for 3-stack cascaded structure of the switch circuit 210A may include conductive elements (e.g., polysilicon) 411, 412, and 413 disposed over the active region 410, as depicted in FIG. 4B. The conductive elements 411, 412, and 413 are supplied with the bias voltages AN, BN, and CN. The source terminal (e.g., n+ diffusion region) of transistor M0 within the switch circuit 210A is located at the left edge of the active region 410, and is supplied with the ground voltage VS. By using the source-outside layout arrangement, the voltage difference between the source terminal of transistor M0 and the conductive element 411 of the switch circuit 210A can be reduced, thereby avoiding high voltage drop from the diffusion region (e.g., source terminal with n+ diffusion) to the well (e.g., body, such as a p-well or p-substrate) within the active region 410.

In some embodiments, the layout of the switch circuit 210B may be symmetric to that of the switch circuit 210A along the horizontal direction. For example, the conductive elements 421, 422, and 423 within the switch circuit 210B are supplied with the bias voltages CN, BN, and AN, respectively. Additionally, the conductive element 421 of the switch circuit 210B is adjacent to the conductive element 413 of the switch circuit 210A. In other words, the layout of the switch circuits 210A and 210B may form a pair. Moreover, the source terminal of the switch circuit 210N (e.g., the last switch circuit 210) is placed at the right edge of the active region 410, and is supplied with the ground voltage VS. By using the source-outside layout arrangement, the voltage difference between the source terminal of transistor M0 and the conductive element 411 within the switch circuit 210N can be reduced, thereby avoiding high voltage drop from the diffusion region (e.g., source terminal with n+ diffusion) to the well (e.g., body, such as a p-well or p-substrate) within the active region 410.

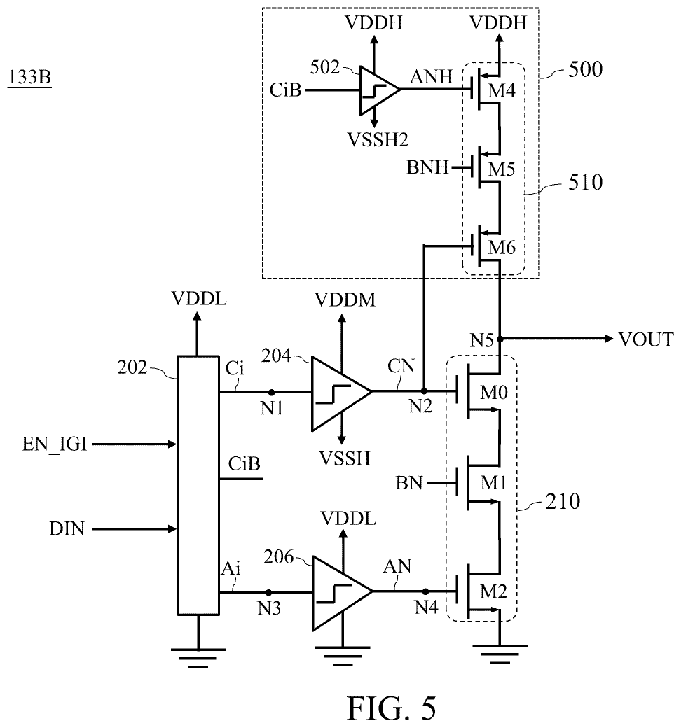

FIG. 5 is a schematic diagram of a gate control circuit in accordance with some embodiments of the present disclosure.

In some embodiments, the gate control circuit 133 shown in FIG. 1 may be implemented using the gate control circuit 133B shown in FIG. 5. The gate control circuit 133B shown in FIG. 5 is similar to the gate control circuit 133A shown in FIG. 2, with the difference being that the gate control circuit 133B uses an active load circuit 500 at its output terminal (e.g., node N5). The active load circuit 500 includes a level shifter 502 and a switch circuit 510. The level shifter is supplied with voltages VDDH and VSSH2. The level shifter 502 may be similar to the level shifters 204 and 206, and can be implemented using the level shifter 300 shown in FIG. 3 with the resistor devices 311 and 312 having larger resistances compared to the level shifters 204 and 206. For example, the larger resistance of the resistor devices 311 and 312 can be implemented using a greater number of diodes (or diode-connected transistors) connected in series or a larger passive resistor.

In some embodiments, the switch circuit 510 (e.g., SWITCH_HVP) may be similar to the switch circuit 210 (e.g., SWITCH_HV), with the difference being that the transistor M4 to M6 within the switch circuit 510 are implemented using P-type transistors with different bias voltages. For example, transistors M4 and M5 are driven by bias voltages ANH and BNH, respectively, while transistor M6 is driven by the bias voltage CN at node N2. The bias voltage BNH is designed to control transistors M4 to M6 within the switch circuit 510 to operate within a safe voltage range, i.e., the voltage difference between any two terminals (e.g., VGS, VDS, and VGD) of the transistors M4, M5, and M6 is controlled to be within 0.75V for safety. For purposes of description, the voltages VDDL, VSSH, VDDH, VDDM, VSSH2, and VS are 0.75V, 0.75V, 2.1V, 1.5V, 1.5V (e.g., 2*VDDL), and 0V, respectively. The configurations of the voltages VOUT, BNH, ANH, CN, BN, AN, Ci, Ai, and CiB are illustrated in Table 3 as follows. In some embodiments, the prebuffer 202 is further capable of generating the voltages CiB, BN and BNH which are within the voltage range between the voltages VDDL and GND.

TABLE 3

| | Switch 510 ON | Switch 510 OFF |
|---|---|---|
| Voltage | Switch 210 OFF | Switch 210 ON |
| VOUT | VDDH | VS |
| BNH | 2*VDDL | 2*VDDL |
| ANH | 2*VDDL(VSSH2) | VDDH |
| CN | 2*VDDL(VDDM) | VDDL(VSSH) |
| BN | VDDL | VDDL |
| AN | VS | VDDL |
| Ci | VDDL | GND |
| Ai | GND | VDDL |
| Cibar | GND | VDDL |

In some embodiments, the operations of the switch circuit 210 in FIG. 5 can be referred to the embodiment of FIG. 4A. The operations of the switch circuit 510 are described as follows. For example, when the gate control circuit 133B is in the DC operation mode (i.e., EN_IGI=0) and the voltage level of the clock signal DIN is equal to the ground voltage (e.g., 0V), the bias voltages CN, BN, and AN provided to the gate terminals of transistors M0, M1, and M2 are equal to the voltage VDDL (e.g., approximately 0.75V), turning on transistors M0 to M2 within the switch circuit 210. At this time, the bias voltages ANH, BNH, and CN, which are provided to the gate terminals of transistors M4, M5, and M6 within the switch circuit 510, are VDDH, 2*VDDL, and VDDL, respectively, turning off transistors M4 to M6. Therefore, the voltage at the output terminal (e.g., node N5) of the gate control circuit 133B is pulled down to the ground voltage VS through transistor M0 to M2. It should be noted that the voltage difference between any two terminals (e.g., VGS, VGD, and VDS) of transistor M4 to M6 is within the safe voltage range using the voltage configurations shown in Table 3. For example, the gate-drain voltage of transistor M6 is approximately 0.75V which is within the safe voltage range. The source voltage of transistor M6, which is also the drain voltage of transistor M5, follows the gate voltage CN of transistor M6. Thus, the gate-drain voltage of transistor M5 is also within the safe voltage range. The source voltage of transistor M5, which is also the drain voltage of transistor M4, follows the gate voltage BNH of transistor M5. Thus, the gate-drain voltage of transistor M4 is also within the safe voltage range. Additionally, the gate-source voltage of transistor M4 is approximately 0V which is within the safe voltage range.

In some embodiments, when the gate control circuit 133B is in the DC operation mode (i.e., EN_IGI=0) and the voltage level of the clock signal DIN is equal to the voltage VDDL (e.g., 0.75V), the bias voltages CN, BN, and AN provided to the gate terminals of transistors M0, M1, and M2 are 2*VDDL (e.g., 1.5V), VDDL (e.g., 0.75V), and VS (e.g., 0V), respectively, turning off transistors M0 to M2 within the switch circuit 210. At this time, the bias voltages ANH, BNH, and CN, which are provided to the gate terminals of transistors M4, M5, and M6 within the switch circuit 510, are equal to the voltage of 2*VDDL (e.g., 1.5V), turning on transistors M4 to M6. Accordingly, the output voltage VOUT at node N5 of the gate control circuit 133B is pulled up to the power supply voltage VDDH. It should be noted that the voltage difference between any two terminals (e.g., VGS, VGD, and VDS) of transistor M4 to M6 is within the safe voltage range using the voltage configurations shown in Table 3. For example, the drain voltage of transistor M4, which is also the source voltage of transistor M5, is close to its source voltage (e.g., VDDH), and thus the gate-source voltage and gate-drain voltage of transistor M4 are within the safe voltage range (e.g., less than or equal to 0.75V). Similarly, the drain voltage of transistor M5, which is also the source voltage of transistor M6, is close to the power supply voltage VDDH, and thus the gate-source voltage and gate-drain voltage of transistor M5 are within the safe voltage range. Likewise, the drain voltage and source voltage of transistor M6 are close to the power supply voltage VDDH, and thus the gate-source voltage and gate-drain voltage of transistor M5 are within the safe voltage range.

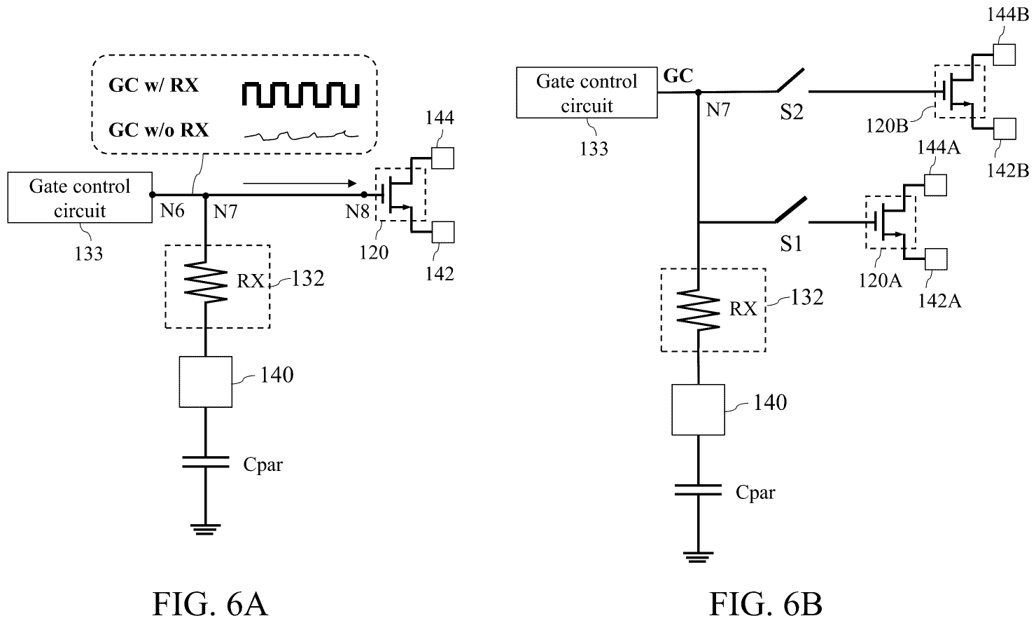

FIG. 6A is a diagram illustrating equivalent resistance and capacitance from the I/O pad to the gate terminal of the DUT in accordance with some embodiments of the present disclosure.

In some embodiments, the gate isolation circuit 132 shown in FIG. 1 may be implemented using a passive resistor RX with a very large resistance, such as within a within a MΩ range (e.g., approximately equal to 1 MΩ). It should be noted that the gate terminal (e.g., node N8) of the DUT 120 shown in FIG. 6A is connected to the I/O pad 140 through the gate isolation circuit 132 (i.e., resistor RX), and the I/O pad 140 includes a parasitic capacitance Cpar, as shown in FIG. 6A. Additionally, the drain terminal and source terminal of the DUT 120 are connected to I/O pads 144 and 142, respectively. For example, when the gate isolation circuit 132 is coupled between the I/O pad 140 and the gate terminal (e.g., node N8) of the DUT 120, the clock signal DIN generated by the clock generator 131 will not be affected by the parasitic capacitance Cpar associated with the I/O pad 140. Specifically, since the resistor RX has a very large resistance, the time constant Rx*Cpar from node N7 to the ground is also large, and the clock signal DIN generated by the clock generator 131 can be kept at substantially the same from the output terminal (e.g., node N6) of the clock generator 131 to the gate terminal (e.g. node N8) regardless of the operating frequency of the clock signal DIN being within the MHz or GHz range. In some approaches, the gate isolation circuit 132 is omitted, indicating that node N7 is directly connected to the I/O pad 140, and the time constant from node N7 to the ground is relatively small. As a result, the GHz clock signal DIN generated by the clock generator 131 can be easily affected by the parasitic capacitance Cpar without the gate isolation circuit 132, and the waveform of the clock signal DIN received by the gate terminal (e.g., node N8) of the DUT 120 can be approximately close to a DC voltage signal, as depicted in FIG. 6A.

FIG. 6B is a diagram illustrating equivalent resistance and capacitance from the I/O pad to the gate terminal of one of the DUTs in accordance with some embodiments of the present disclosure.

In some embodiments, FIG. 6B is similar to FIG. 6A, with the difference being that multiple DUTs 120 are employed within the integrated circuit 100, and DUTs 120A-120B are connected to the clock generator 131 through the respective switches. For purposes of description, two DUTs 120A-120B and their respective switches S1 and S2 are shown in FIG. 6B. It should be noted that the integrated circuit 100 can include more DUTs therein. Additionally, the drain terminal and source terminal of the DUT 120A are connected to the respective I/O pads 144A and 142A, while the drain terminal and source terminal of the DUT 120B are connected to the respective I/O pads 144B and 142B.

In some embodiments, each DUT 120A-120B is tested sequentially, indicating that one of the switches S1 and S2 is activated, and the other of the switches S1 and S2 is deactivated. Additionally, the DUTs 120A and 120B share the same gate isolation circuit 132. For example, the DUT 120A is tested first, indicating that switch S1 is activated (e.g., closed) and switch S2 is deactivated (e.g., open). Thus, the gate terminal of the DUT 120A is connected to the gate isolation circuit 132 and the clock generator 131, and the clock signal DIN transmitted from the clock generator 131 to the gate terminal of the DUT 120A can be maintained without being affected by the parasitic capacitance Cpar of the I/O pad 140. Subsequently, the DUT 120B is tested, indicating that the switch S2 is activated (e.g., closed) and switch S1 is deactivated (e.g., open). Thus, the gate terminal of the DUT 120A is connected to the gate isolation circuit 132 and the clock generator 131, and the clock signal DIN transmitted from the clock generator 131 to the gate terminal of the DUT 120B can be maintained without being affected by the parasitic capacitance Cpar of the I/O pad 140.

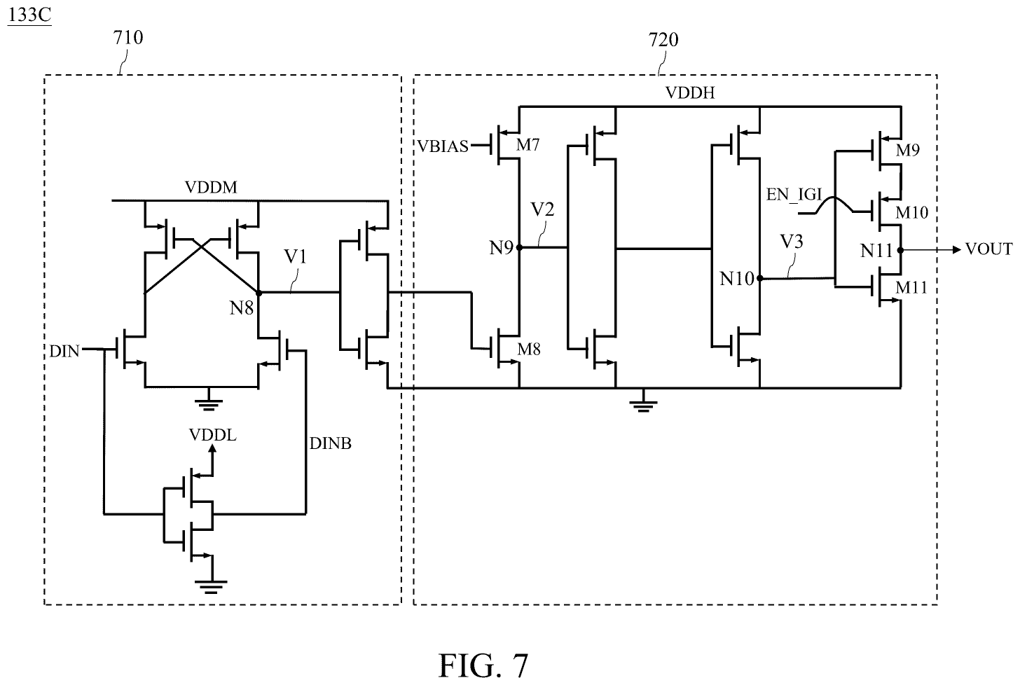

FIG. 7 is a schematic diagram of a gate control circuit in accordance with some embodiments of the present disclosure.

In some embodiments, the gate control circuit 133 shown in FIG. 1 is implemented using the gate control circuit 133C shown in FIG. 7, and the transistors within the gate control circuit 133C are I/O-device transistors which have a larger tolerance voltage range compared to the core-device transistors. In some embodiments, the I/O-device transistors may be fabricated using a less advanced semiconductor manufacturing process, and the voltage difference between any two terminals (e.g., VGS, VGD, and VDS) of an I/O-device transistor can be up to approximately 1.1V. Thus, the complexity for designing the bias voltages and control scheme for I/O devices can be reduced. It should be noted that transistors fabricated by an advanced semiconductor manufacturing process can be core devices with a relatively lower tolerance voltage range (e.g., 0.75V).

In some embodiments, the gate control circuit 133C includes level shifters 710 and 720. The level shifter 710 may be configured to convert the clock signal DIN within a first voltage range to generate a voltage signal V1 within a second voltage range at node N8. The level shifter 720 is configured to convert the voltage signal V1 within the second voltage range to an output voltage VOUT within a third voltage range. For example, the first voltage range of the clock signal DIN is between the voltage VDDL (e.g., 0.75V) and the ground (e.g., 0V), the second voltage range of the voltage signal V1 is between the voltage VDDM (e.g., 1.5V) and the ground, and the third voltage range is between the voltage VDDH (e.g., 2.1V) and the ground. Additionally, the voltage VDDM (e.g., 1.5V) is higher than the voltage VDDL (e.g., 0.75V). The transistors M7 is biased by a voltage VBIAS. The transistors M7 and M8 within the level shifter 720 may convert the voltage signal V1 to generate a voltage signal V2 within a third voltage range at node N9.

In some embodiments, the gate control circuit 133C is designed to handle the gate leakage current (Igi) calibration, and the operations of the output stage (e.g., M9 to M11) of the level shifter 720 are described as follows. For purposes of description, when the test enable signal EN_IGI is in the high logic state (e.g., “1” or VDDH) and the low logic state (e.g., “0”), the voltage VBIAS is equal to the voltage VDDH (e.g., 2.1V) and the voltage VDDM (e.g., 1.5V), respectively. In some embodiments, when the test enable signal EN_IGI is in the high logic state (e.g., “1”) and the clock signal DIN is in the low logic state (e.g., “0”), the voltage signal V1 is pulled down to the ground voltage (e.g., 0V), causing the gate voltage of transistor M8 being in the high logic state (e.g., VDDM), and turning on transistor M8. Meanwhile, transistor M7 is turned off, and the voltage signal V2 at node N9 is pulled down to the ground voltage. The voltage signal V2 passes through a buffer (i.e., two inverters), and the voltage signal V3 at node N10 is substantially equal to the voltage signal V2 which is equal to the ground voltage.

In some embodiments, the voltage signal V3 serves as the gate voltage of transistors M9 and M11, turning off transistor M11. Since transistor M10 is turned off (i.e., EN_IGI=“1”), transistor M9 is turned off accordingly. It should be noted that the output voltage VOUT at the output terminal (e.g., node N11) of the gate control circuit 133C is connected to the gate terminal of the DUT 120. It should be noted that transistor M10 is also turned off since its gate voltage (i.e., EN_IGI) is in the high logic state (e.g., VDDH). The external test equipment (not shown) can measure the gate leakage current, via the I/O pad 140, flowing into the output terminal (e.g., node N11) of the gate control circuit 133C through the gate isolation circuit 132. Specifically, the gate leakage current Igi includes a first leakage current Ioff_M11 and a second leakage current Ioff_M9M10. The first leakage current Ioff_M11 flows from node N11 to the ground through transistor M3, while the second leakage current Ioff_M9M10 flows from node N11 to the power rail of the voltage VDDH through transistors M10 and M9.

In some embodiments, when the test enable signal EN_IGI is in the low logic state (e.g., “0”), the level shifters 710 and 720 can work in a normal DC operation mode. When the clock signal DIN is in the low logic state (e.g., “0”), since the test enable signal EN_IGI and the voltage signal V3 are both in the low logic state as described, transistors M9 and M10 are turned on and transistor M11 is turned off, pulling up the output voltage VOUT to the voltage VDDH. When the clock signal DIN is in the high logic state (e.g., “1” or VDDL), the voltage signal V1 is pulling up to the voltage VDDM, causing the gate voltage of transistor M8 is in the low logic state and turning off transistor M8. Since transistor M7 is turned on, the voltage signal V2 at node N9 is pulled up to the voltage VDDH, and the voltage signal V3 at node N10 follows the voltage signal V2. As a result, transistor M9 is turned off and transistor M11 is turned on, pulling down the output voltage VOUT to the ground. It should be noted that since transistor M9 is turned off, the conductive path from the voltage VDDH to node N11 is cut off.

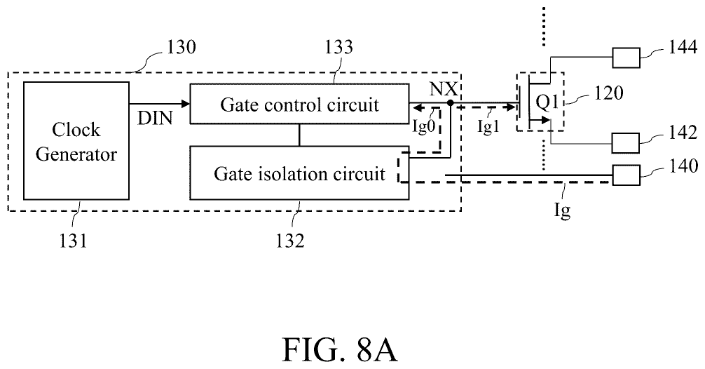

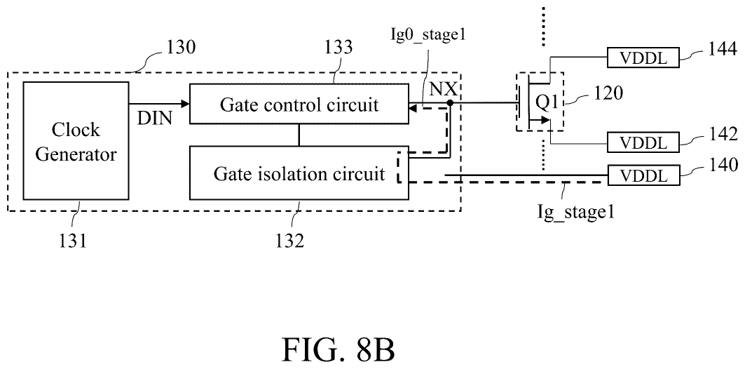

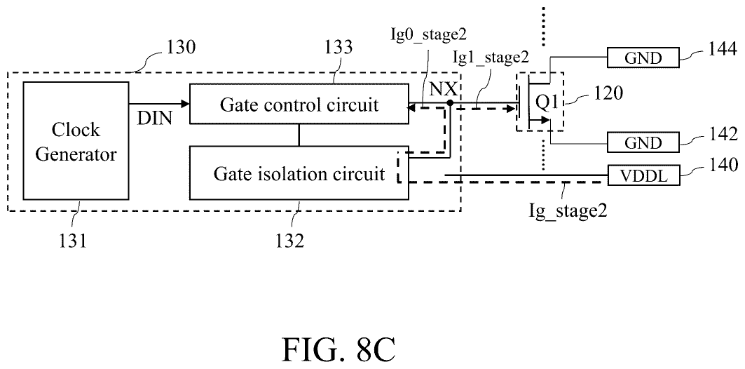

FIG. 8A is a diagram illustrating the components of a gate leakage current measured from the I/O pad in accordance with some embodiments of the present disclosure. FIGS. 8B-8C are diagrams illustrating the procedure for calibrating a gate leakage current of the DUT in accordance with some embodiments of the present disclosure.

In some embodiments, an N-type field-effect transistor (e.g., abbreviated as “transistor”) Q1 may be used as the DUT 120. The transistor Q1 has a gate terminal connected to node NX, a drain terminal connected to the I/O pad 144, and a source terminal connected to the I/O pad 142, as depicted in FIG. 8A. Additionally, the gate isolation circuit 132 is coupled between the I/O pad 140 and node N1. It should be noted that the I/O pad 140, 142, and 144 can be regarded as off-chip components which have respective parasitic capacitance and resistance.

In some embodiments, external test equipment can measure the overall gate leakage current Ig at the I/O pad 140, which is connected to the gate terminal of the DUT 120 through the gate isolation circuit 132 (e.g., a very large resistor). As depicted in FIG. 8A, the overall gate leakage current Ig from the I/O pad 140 to node NX includes two components, namely, gate leakage currents Ig0 and Ig1. The gate leakage current Ig0 refers to the current flowing from node NX into the output terminal of the gate control circuit 133, while the gate leakage current Ig1 refers to the current flowing from node NX into the gate terminal of the DUT 120. During calibration of the gate leakage current of the DUT 120, the gate leakage current Ig1 of the DUT 120 cannot be directly measured by the external test equipment since the test circuit 130 and the DUT 120 are within the integrated circuit 100. In particular, the gate leakage current Ig1 can be indirectly measured by subtracting the gate leakage current Ig0 from the overall gate leakage current Ig0.

During the first stage, a calibration operation for the gate leakage current of the DUT 120 is performed, and the voltage VDDL are provided to the I/O pads 140, 142, and 144, as shown in FIG. 8B. Since source voltage and the drain voltage of the DUT 120 is equal to its gate voltage, the leakage currents from the gate terminal (e.g., gate oxide) of the DUT 120 to the source terminal and drain terminal (e.g., n+ diffusion region) can be substantially eliminated, indicating that the gate leakage current Ig1_stage1 is substantially equal to 0, which is omitted from FIG. 8B. Thus, the overall gate leakage current Ig_stage1 measured by the external test equipment is equal to the gate leakage current Ig0_stage1. It should be noted that during calibration of the gate leakage current of the DUT 120, the switch circuit 210 within the gate control circuit 133 has high impedance (HZ), while the load circuit 208 or active load circuit 500 has high impedance, as described in the embodiments of FIG. 2 and FIG. 5.

Furthermore, the transistors within the gate control circuit 133A or 133B are core-device transistors, as described in the embodiments of FIG. 2 and FIG. 5. When the test enable signal EN_IGI is in the high-logic state (e.g., “1”), a leakage current flow from node N5 to the ground through transistors M0 to M2. Additionally, as described in the embodiment of FIG. 7, the transistors within the gate control circuit 133C are I/O-device transistors. When the test enable signal EN_IGI is in the high-logic state (e.g., “1”), the leakage current flowing into the output terminal (e.g., node N11) of the gate control circuit 133C includes a first leakage current Ioff_M11 and a second leakage current Ioff_M9M10. The first leakage current Ioff_M11 flows from node N11 to the ground through transistor M3, while the second leakage current Ioff_M9M10 flows from node N11 to the power rail of the voltage VDDH through transistors M10 and M9.

During the second stage, the actual gate leakage current of the DUT 120 is estimated. For example, the voltages VDDL, GND, and GND are provided to the I/O pads 140, 142, and 144, respectively, as shown in FIG. 8C. Since the gate-source voltage and gate-drain voltage of the DUT 120 is a non-zero voltage, the gate leakage current Ig1_stage2 include a gate leakage current flowing from the gate terminal of the DUT 120 to the source terminal (e.g., n+ diffusion region), and another gate leakage current flowing from the gate terminal of the DUT 120 to the drain terminal (e.g., n+ diffusion region). It should be noted that the leakage current Ig0_stage2 within the second stage, which cannot be directly measured during the second stage, is equal to the leakage current Ig0_stage1 within the first stage since the gate terminal of the DUT 120 is maintained at the voltage VDDL through the I/O pad 140 and the gate isolation circuit 132. Thus, the overall gate leakage current Ig_stage2 measured by the external test equipment during the second stage is the sum of the leakage currents Ig0_stage2 and Ig1_stage2. Therefore, the external test equipment can measure the gate leakage current Ig1_stage2 of the DUT 120 by subtracting the Ig0_stage1 from the Ig_stage2.

During the third stage, the clock generator 131 is activated to perform a GHz stress test on the DUT 120, and the gate control circuit 133 is performed in a normal DC operation mode to convert the clock signal DIN within a lower voltage range (e.g., between 0 and 0.75V) to a clock signal GC within a higher voltage range (e.g., between 0 and 1.5V). Additionally, the I/O pad 140 has high impedance (HZ), and the clock signal GC can be maintained from the output terminal of the gate control circuit 133 to the gate terminal of the DUT 120 with the assist of the gate isolation circuit 132. Accordingly, the DUT 120 can be stressed by the high-voltage GHz clock signal GC.

It should be noted that stages 1 to 3 can be repeatedly performed for each DUT 120, thereby estimating the gate leakage current Igi of each DUT 120 and performing high-voltage GHz stress test on each DUT 120 to determine the reliability of each DUT 120. Additionally, negative bias temperature instability (NBTI) and time-dependent dielectric breakdown (TDDB) of each DUT 120 can also be estimated through stages 1 to 3.

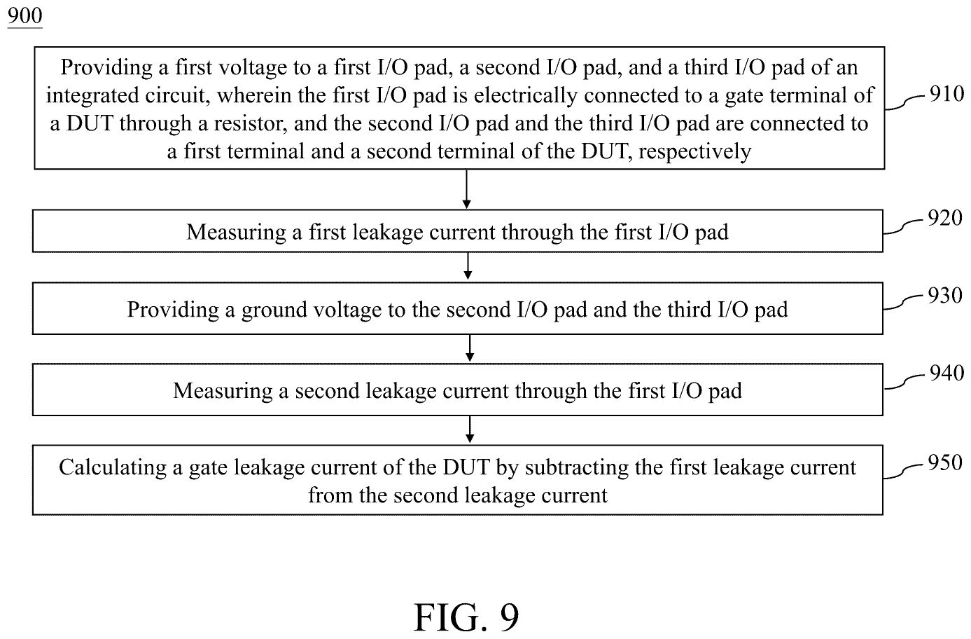

FIG. 9 is a flowchart of a method for calibrating a gate leakage current of the DUT in accordance with some embodiments of the present disclosure. Please refer to both FIG. 1 and FIG. 9.

In operation 910, a first voltage is provided to a first I/O pad, a second I/O pad, and a third I/O pad of an integrated circuit, wherein is the first I/O pad is electrically connected to a gate terminal of a device under test (DUT) through a resistor, and the second I/O pad and the third I/O pad are connected to a first terminal and a second terminal of the DUT, respectively. For example, the first voltage is provided to the gate terminal of the selected DUT 120 through the first I/O pad (e.g., I/O pad 140) and the gate isolation circuit 132, while the first voltage is provided to the first terminal (e.g., drain terminal) and the second terminal (e.g., source terminal) through the second I/O pad (e.g., I/O pad 144) and the third I/O pad (e.g., I/O pad 142), respectively. In some embodiments, the gate isolation circuit 132 is coupled between the first I/O pad (e.g., I/O pad 140) and the gate terminal of the selected DUT 120. The gate control circuit 133 may provide a high output impedance (HZ) when a test for calibrating the gate leakage current of the selected DUT 120 is performed, and provide a gate clock signal GC to the gate terminal of the selected DUT 120 during a stress test of the DUT 120.

In operation 920, a first leakage current is measured through the first I/O pad. Referring to FIG. 8, the first leakage current may refer to the leakage current Ig_stage1 which is equal to the leakage current Ig0_stage1 flowing into the output terminal of the gate control circuit 133. Since source voltage and the drain voltage of the selected DUT 120 is equal to its gate voltage, the leakage currents from the gate terminal of the selected DUT 120 to the source terminal and drain terminal (e.g., n+ diffusion region) can be substantially eliminated, indicating that the gate leakage current Ig1_stage1 is substantially equal to 0.

In operation 930, a ground voltage is provided to the second I/O pad and the third I/O pad. In some embodiments, since the gate-source voltage and gate-drain voltage of the DUT 120 is a non-zero voltage, the gate leakage current Ig1_stage2 include a gate leakage current flowing from the gate terminal of the DUT 120 to the source terminal (e.g., n+ diffusion region), and another gate leakage current flowing from the gate terminal of the DUT 120 to the drain terminal (e.g., n+ diffusion region).

In operation 940, a second leakage current is measured through the first I/O pad. In some embodiments, the leakage current Ig0_stage2 within the second stage is equal to the leakage current Ig0_stage1 within the first stage since the gate terminal of the DUT 120 is maintained at the voltage VDDL through the I/O pad 140 and the gate isolation circuit 132.

In operation 950, a gate leakage current of the DUT is calculated by subtracting the first leakage current from the second leakage current. In some embodiments, the external test equipment can measure the gate leakage current Ig1_stage2 of the DUT 120 by subtracting the Ig0_stage1 from the Ig_stage2.

An aspect of the present disclosure provides an integrated circuit, which includes a device under test (DUT) and a test circuit. The test circuit includes a clock generator, a gate control circuit, and a gate isolation circuit. The clock generator is configured to generate a clock signal. The gate control circuit is configured to convert, in response to a test enable signal being deasserted, the clock signal within a first voltage domain to generate a gate clock signal within a second voltage domain at an output terminal of the gate control circuit which is connected to a gate terminal of the DUT. The gate isolation circuit is coupled between the gate terminal of the DUT and a first input/output (I/O) pad of the integrated circuit.

Another aspect of the present disclosure provides an integrated circuit, which includes a device under test (DUT) and a test circuit. The DUT includes a gate terminal, a first terminal, and a second terminal. The test circuit includes a gate control circuit and a gate isolation circuit. The gate control circuit is configured to switch to a high-impedance state at an output terminal of the gate control circuit which is connected to a gate terminal of the DUT in response to a test enable signal being asserted. The gate isolation circuit is coupled between the gate terminal of the DUT and a first input/output (I/O) pad of the integrated circuit. The first terminal and the second terminal of the DUT are coupled to a second I/O pad and a third I/O pad of the integrated circuit.

Yet another aspect of the present disclosure provides a method, which includes the following steps: providing a first voltage to a first I/O pad, a second I/O pad, and a third I/O pad of an integrated circuit, wherein is the first I/O pad is electrically connected to a gate terminal of a device under test (DUT) through a resistor, and the second I/O pad and the third I/O pad are connected to a first terminal and a second terminal of the DUT, respectively; measuring a first leakage current through the first I/O pad; providing a ground voltage to the second I/O pad and the third I/O pad; measuring a second leakage current through the first I/O pad; and calculating a gate leakage current of the DUT by subtracting the first leakage current from the second leakage current.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. An integrated circuit, comprising:
a device under test (DUT); and
a test circuit, comprising:
a clock generator, configured to generate a clock signal;
a gate control circuit, configured to convert, in response to a test enable signal being deasserted, the clock signal within a first voltage domain to generate a gate clock signal within a second voltage domain at an output terminal of the gate control circuit which is connected to a gate terminal of the DUT; and
a gate isolation circuit, coupled between the gate terminal of the DUT and a first input/output (I/O) pad of the integrated circuit.

2. The integrated circuit of claim 1, wherein the second voltage domain is higher than the first voltage domain.

3. The integrated circuit of claim 1, wherein the clock signal within a GHz range.

4. The integrated circuit of claim 1, wherein the DUT comprises a first terminal and a second terminal connected to a second I/O pad and a third I/O pad of the integrated circuit, respectively.

5. The integrated circuit of claim 1, wherein the first I/O pad is in a high-impedance status.

6. The integrated circuit of claim 1, wherein the gate isolation circuit comprises a resistor having a resistance within a MΩ range.

7. The integrated circuit of claim 1, wherein the gate control circuit comprises:
a prebuffer, configured to receive the test enable signal and the clock signal to generate a first voltage signal, a second voltage signal, and a third voltage signal;
a first level shifter, configured to convert the first voltage signal to a first bias voltage signal;
a second level shifter, configured to convert the third voltage signal to a second bias voltage signal;
a switch circuit, coupled between the output terminal of the gate control circuit and a ground terminal, and configured to operate based on the first bias voltage signal, the second voltage signal, and the second bias voltage signal; and
a load circuit, coupled to a first power rail and the output terminal of the gate control circuit.

8. The integrated circuit of claim 7, wherein the first level shifter and the second level shifter have substantially equal delay.

9. The integrated circuit of claim 7, wherein in response to the test enable signal being deasserted, a first power supply voltage is provided to the first power rail.

10. The integrated circuit of claim 9, wherein the first level shifter operates within a third voltage domain which is between a second power supply voltage and a reference voltage, and the second level shifter operates within the first voltage domain which is between a third power supply voltage and a ground voltage.

11. The integrated circuit of claim 10, wherein:
the switch circuit comprises a first transistor, a second transistor, and a third transistor stacked in a cascade structure from the output terminal of the gate control circuit to the ground terminal; and
the first transistor, the second transistor, and the third transistor are controlled by the first bias voltage signal, the second voltage signal, and the second bias voltage signal.

12. The integrated circuit of claim 11, wherein in response to the test enable signal being asserted, the first bias voltage signal, the second voltage signal, and the second bias voltage signal are tied to the ground voltage, and the first power supply voltage is not provided to the first power rail.

13. The integrated circuit of claim 11, wherein:
the first transistor, the second transistor, and the third transistor comprise a first conductive element, a second conductive element, and a third conductive element disposed over an active region in parallel along a first direction; and
the first conductive element, the second conductive element, and the third conductive element are supplied with the first bias voltage signal, the second voltage signal, and the second bias voltage signal.

14. The integrated circuit of claim 13, wherein a source terminal of the third transistor is proximate to an edge of the active region along the first direction.

15. An integrated circuit, comprising:
a device under test (DUT), comprising a gate terminal, a first terminal, and a second terminal; and
a test circuit, comprising:
a gate control circuit, configured to switch to a high-impedance state at an output terminal of the gate control circuit which is connected to a gate terminal of the DUT in response to a test enable signal being asserted; and
a gate isolation circuit, coupled between the gate terminal of the DUT and a first input/output (I/O) pad of the integrated circuit,
wherein the first terminal and the second terminal of the DUT are coupled to a second I/O pad and a third I/O pad of the integrated circuit.

16. The integrated circuit of claim 15, wherein the gate isolation circuit comprises a resistor having a resistance within a MΩ range.

17. The integrated circuit of claim 15, wherein the test circuit further comprises a clock generator configured to generate a clock signal within a first voltage domain, and the gate control circuit is further configured to convert the clock signal to generate a gate clock signal within a second voltage domain in response to the test enable signal being deasserted.

18. A method, comprising:
providing a first voltage to a first I/O pad, a second I/O pad, and a third I/O pad of an integrated circuit, wherein the first I/O pad is electrically connected to a gate terminal of a device under test (DUT) through a resistor, and the second I/O pad and the third I/O pad are connected to a first terminal and a second terminal of the DUT, respectively;
measuring a first leakage current through the first I/O pad;
providing a ground voltage to the second I/O pad and the third I/O pad;
measuring a second leakage current through the first I/O pad; and
calculating a gate leakage current of the DUT by subtracting the first leakage current from the second leakage current.

19. The method of claim 18, wherein the resistor has a resistance within a MΩ range.

20. The method of claim 18, wherein the gate leakage current of the DUT comprises a first leakage current from the gate terminal to the first terminal of the DUT and a second leakage current from the gate terminal to the second terminal of the DUT.
